(19) United States
(12) Patent Application Publication
(10) Pub. No.: US 2021/0087077 A1
(43) Pub. Date: Mar. 25, 2021

(54) Fluid Sterilizer

(71) Applicant: Toshiba Lighting & Technology Corporation, Yokosuka-shi (JP)

(72) Inventors: Naoto Sakurai, Imabari-shi (JP); Takeo Kato, Imabari-shi (JP)

(73) Assignee: Toshiba Lighting & Technology Corporation, Yokosuka-shi (JP)

(21) Appl. No.: 17/014,116

(22) Filed: Sep. 8, 2020

(30) Foreign Application Priority Data
Sep. 24, 2019 (JP) 2019-173436

(51) Int. Cl. C02F 1/32; H05K 7/20

(52) U.S. Cl. CPC C02F 1/325; H05K 7/20254; C02F 2201/3227; C02F 2201/3222; C02F 2303/04

(57) ABSTRACT

A fluid sterilizer of an embodiment includes a processing chamber, a light source unit, and a supply flow path. The processing chamber processes a fluid. The light source unit has a light source, a cooling block, and a medium flow path. The light source irradiates the processing chamber with ultraviolet rays. The cooling block cools the light source. The medium flow path is provided inside the cooling block, and a cooling medium flows therein. The supply flow path connects the medium flow path and the processing chamber to each other, and supplies the cooling medium flowing through the medium flow path to the processing chamber as the fluid.

### CROSS-REFERENCE TO RELATED APPLICATION

This application is based upon and claims the benefit of priority from the Japanese Patent Application No. 2019-173436, filed on Sep. 24, 2019; the entire contents of which are incorporated herein by reference.

### FIELD

Embodiments described herein relate to a fluid sterilizer.

### BACKGROUND

There is a known fluid sterilizer that irradiates, for example, a flow path, through which a fluid such as water or gas flows, with ultraviolet rays emitted from a light-emitting element of a light source, thereby sterilizing the fluid. Some fluid sterilizers of this type have a substrate on which a light emitting diode (LED) that emits ultraviolet rays is mounted as a light source.

Incidentally, in the case of irradiating the fluid flowing through the flow path with ultraviolet rays, etc. from the LED to sterilize the fluid, when the output of the LED is increased and the fluid is efficiently irradiated, a higher sterilization effect can be obtained. However, LEDs have a temperature limit due to heat generation. For this reason, when the power input to the LED is merely increased or the number of mounted LEDs is merely increased, the light emission efficiency of the LED decreases due to the heat generated by the light emission, and thus a high output may not be obtained, and it may be difficult to effectively obtain the sterilization effect.

A problem to be solved by the present disclosure is to provide a fluid sterilizer that can efficiently obtain the sterilization effect.

### BRIEF DESCRIPTION OF THE DRAWINGS

FIG. 1 is a schematic diagram illustrating an application example of a fluid sterilizer according to a first embodiment.

FIG. 2 is a schematic cross-sectional view illustrating a main part of the fluid sterilizer.

FIG. 3 is a schematic diagram illustrating a light source unit according to the first embodiment.

FIG. 4 is a schematic cross-sectional view illustrating a main part of a fluid sterilizer according to a second embodiment.

FIG. 5 is a schematic cross-sectional view illustrating a main part of a fluid sterilizer according to a third embodiment.

FIG. 6 is a schematic cross-sectional view illustrating a main part of a fluid sterilizer according to a fourth embodiment.

FIG. 7 is a schematic cross-sectional view illustrating a main part of a fluid sterilizer according to a fifth embodiment.

FIG. 8 is a schematic cross-sectional view illustrating a main part of a fluid sterilizer according to a sixth embodiment.

FIG. 9 is a schematic cross-sectional view illustrating a main part of a fluid sterilizer according to a seventh embodiment.

FIG. 10 is a schematic cross-sectional view illustrating a main part of a fluid sterilizer according to an eighth embodiment.

FIG. 11 is a schematic cross-sectional view illustrating a main part of a fluid sterilizer according to a ninth embodiment.

### DETAILED DESCRIPTION

A fluid sterilizer 1 according to an embodiment described below includes a processing chamber 20, a light source units 10, 10a to 10c, and a supply flow path 5. The processing chamber 20 processes a fluid. The light source units 10, 10a to 10c have a light source 14, a cooling block 11, and a medium flow path 17. The light source 14 emits ultraviolet rays toward the processing chamber 20. The cooling block 11 cools the light source 14. The medium flow path 17 is provided inside the cooling block 11, and a cooling medium flows therein. The supply flow path 5 connects the medium flow path 17 and the processing chamber 20 to each other. The supply flow path 5 supplies the cooling medium flowing through the medium flow path 17 to the processing chamber 20 as the fluid.

In addition, the light source units 10, 10a to 10c according to embodiments below have a plurality of light sources 14 having different irradiation directions.

In addition, the light source units 10b and 10c according to an embodiment described below have a light source 14b facing a side surface 203 of the processing chamber 20.

In addition, the light source units 10, 10a to 10c according to the embodiments described below have a plurality of cooling blocks 11, 11a to 11c in which medium flow paths 17, 17a to 17c are connected in parallel via connection flow paths 9, 9a to 9c.

In addition, the light source units 10, 10a to 10c according to the embodiments described below have a plurality of cooling blocks 11, 11a to 11c in which medium flow paths 17, 17a to 17c are connected in series via connection flow paths 9d to 9f.

Further, in the fluid sterilizer 1 according to the embodiment described below, at least a part of the light source units 10, 10a to 10c including the medium flow paths 17, 17a to 17c is detachably mounted.

Hereinafter, the fluid sterilizer according to the embodiments will be described with reference to the drawings. Note that the following embodiments are merely examples, and do not limit the invention. In addition, the respective embodiments described below can be appropriately combined within a range that does not contradict. Further, in the description of each embodiment, the same reference symbols are given to the same configurations, and later description is omitted as appropriate.

### First Embodiment

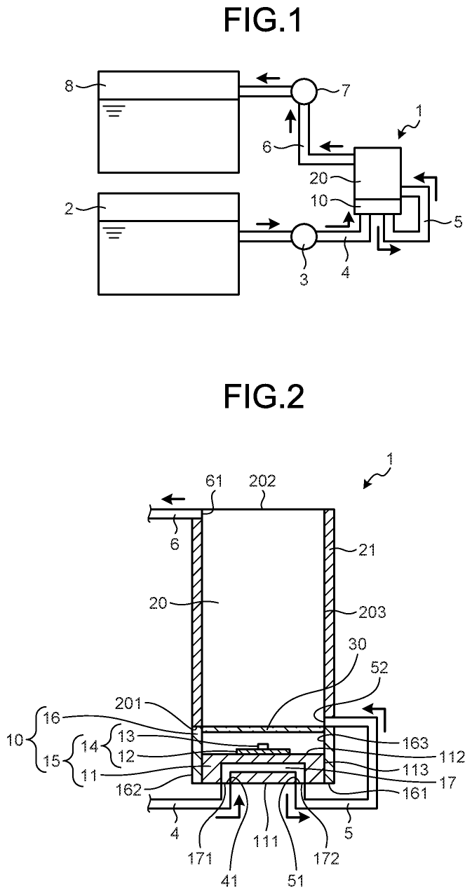

FIG. 1 is a schematic diagram illustrating an application example of a fluid sterilizer according to a first embodiment. FIG. 2 is a schematic cross-sectional view illustrating a main part of the fluid sterilizer according to the first embodiment.

As illustrated in FIG. 1, a fluid sterilizer 1 of the first embodiment includes a processing chamber 20 that processes a fluid, a light source unit 10 that irradiates the processing chamber 20, and a supply flow path 5 that supplies the fluid to the processing chamber 20. The light source unit 10 of the fluid sterilizer 1 is connected to a supply tank 2 via an upstream side flow path member 4, and the processing chamber 20 of the fluid sterilizer 1 is connected to a recovery tank 8 via a downstream side flow path member 6. Further, the light source unit 10 and the processing chamber 20 are connected via the supply flow path 5.

That is, the fluid sterilizer 1 sterilizes the fluid supplied from the supply tank 2 and supplies the sterilized fluid to the recovery tank 8. One end of the upstream side flow path member 4 is connected to the supply tank 2, and the other end is connected to the light source unit 10 of the fluid sterilizer 1. A pump 3 is provided in the upstream side flow path member 4.

The pump 3 has a function of sending the fluid in the supply tank 2 to the light source unit 10 and the processing chamber 20 of the fluid sterilizer 1 via the upstream side flow path member 4. One end of the downstream side flow path member 6 is connected to the processing chamber 20, and the other end is connected to the recovery tank 8. The downstream side flow path member 6 is provided with a flow rate adjusting mechanism 7 that adjusts a flow rate of the fluid sent from the fluid sterilizer 1 to the recovery tank 8. In addition, as illustrated in FIG. 1, for example, the downstream side flow path member 6 is attached to a side surface of the processing chamber 20. Note that an attachment position of the downstream side flow path member 6 is not limited to a configuration illustrated in FIG. 1, and may be any position as long as the position faces the light source unit 10.

The fluid sterilizer 1 is used, for example, in a drinking water supply apparatus to sterilize water in the supply tank 2. In the present embodiment, as the fluid, for example, a liquid such as clean water is applied. However, a gas may be applied.

As illustrated in FIG. 2, the fluid sterilizer 1 includes the processing chamber 20, the light source unit 10, a cover member 30, and the supply flow path 5.

The processing chamber 20 is a space formed of, for example, quartz glass that transmits ultraviolet rays, and processes the fluid contained therein. A shape of the processing chamber 20 may be, for example, a cylindrical shape, and is not particularly limited. For example, it is possible to adopt a box shape or a rectangular tube shape.

A reflection plate 21 is arranged on a side surface 203 of the processing chamber 20. The reflection plate 21 reflects ultraviolet rays penetrating the side surface 203 toward the inside of the processing chamber 20. Further, instead of the reflection plate 21, a reflection film may be arranged on the side surface 203 of the processing chamber 20. The reflection film is, for example, a silica film or an aluminum vapor deposition film. Further, the reflection plate 21 or the reflection film may be arranged on an inner surface of the processing chamber 20. Further, the processing chamber 20 may have both the reflection plate 21 and the reflection film, or may not have the reflection plate 21 or the reflection film. Further, the processing chamber 20 may have one or both of the reflection plate 21 and the reflection film on an end face 202 separated from the light source unit 10.

The light source unit 10 irradiates the inside of the processing chamber 20 with ultraviolet rays. In addition, the light source unit 10 includes a light source 14, a cooling block 11, and a medium flow path 17.

The light source 14 has a substrate 12 and a light-emitting element 13 mounted on the substrate 12. The substrate 12 is formed using a metal material as a base material. Although not illustrated, a desired conductive pattern (wiring pattern) is formed on the substrate 12 via an insulating layer, and the light-emitting element 13 is provided on the conductive pattern. Note that the base material of the substrate 12 is not limited to the metal material, and ceramics such as alumina may be used. The substrate 12 is fixed to a front surface 112 of the cooling block 11.

The light-emitting element 13 is mounted on the substrate 12 and emits ultraviolet rays by lighting. The light-emitting element 13 is, for example, an LED. The light-emitting element 13 is supplied with power from a power source (not illustrated) and emits light. The light-emitting element 13 is arranged to face an end face 201 of the processing chamber 20, and irradiates the processing chamber 20 with ultraviolet rays. Further, the light-emitting element 13 may have a peak wavelength in the vicinity of a wavelength of 280 nm in consideration of life and output. However, it is sufficient that the light-emitting element 13 emits ultraviolet rays in a wavelength band having a germicidal action such as 260 nm to 280 nm, and the wavelength of ultraviolet rays emitted by the light-emitting element 13 is not limited. That is, the light-emitting element 13 is not limited to the LED, and may be another semiconductor element such as a laser diode (LD) that emits ultraviolet rays in a predetermined wavelength band. In addition, the number of the light-emitting elements 13 mounted on the substrate 12 is not limited, and for example, the number of the light-emitting elements 13 may be one or may be plural. When a plurality of light-emitting elements 13 is mounted on the substrate 12, peak wavelengths of the respective light-emitting elements 13 may be different from each other. Further, the light source unit 10 may have a plurality of substrates 12, and the number of light-emitting elements 13 mounted on the plurality of substrates 12 may be different. In addition, when a plurality of substrates 12 is mounted on the light source unit 10, peak wavelengths of the light-emitting elements 13 mounted on the respective substrates 12 may be different from each other, or the peak wavelengths of the plurality of light-emitting elements 13 mounted on one substrate 12 may be different from each other.

The cooling block 11 supports the light source 14 by fixing the substrate 12 on which the light-emitting element 13 is mounted at a predetermined position. Here, the light-emitting element 13 needs to be replaced periodically since the light emitting efficiency decreases as the lighting time elapses. For this reason, in the fluid sterilizer 1, in order to facilitate replacement of the light source 14, a mounting portion 15 which is a part of the light source unit 10 is configured to be easily removable. Details of this point will be described later.

The medium flow path 17 is formed inside the cooling block 11. On a back surface 111 of the cooling block 11, openings 171 and 172 that are both ends of the medium flow path 17 are formed. Further, an end portion 41 of the upstream side flow path member 4 and an end portion 51 of the supply flow path 5 are connected to the openings 171 and 172, respectively. As a result, the fluid from the supply tank 2 is supplied to the medium flow path 17, and heat exchange occurs between the light source 14 and the fluid flowing through the medium flow path 17 via the cooling block 11. That is, the fluid flowing through the medium flow path 17 behaves as a cooling medium. Note that the end portion 41 may be inserted into the opening 171 or may be connected to a joint member (not illustrated) inserted into the opening 171. Similarly, the end portion 51 may be inserted into the opening 172 or may be connected to a joint member (not illustrated) inserted into the opening 172.

The cover member 30 is a plate-shaped member that transmits ultraviolet rays. Specifically, for example, quartz glass can be used as the cover member 30. The cover member 30 is arranged between the processing chamber 20 and the light source unit 10 so that an inner space of the light source unit 10 is airtight, and partitions the processing chamber 20 through which the fluid flows and the light source unit 10. The cover member 30 transmits the ultraviolet rays emitted from the light-emitting element 13 and irradiates the processing chamber 20 with the ultraviolet rays to sterilize the fluid flowing inside the processing chamber 20. Note that a material of the cover member 30 is not limited to quartz glass, and may be, for example, calcium fluoride (CaF₂) that transmits ultraviolet rays.

The supply flow path 5 is a flow path member that supplies the fluid to the processing chamber 20. One end (end portion 51) of the supply flow path 5 is connected to the medium flow path 17, and the other end (end portion 52) is connected to the processing chamber 20. The supply flow path 5 allows the medium flow path 17 and the processing chamber 20 to communicate each other, thereby supplying the fluid flowing through the medium flow path 17 to the processing chamber 20. By providing the supply flow path 5 in this way, the fluid sterilizer 1 can use the fluid before processing in the processing chamber 20 as a cooling medium. Since it is unnecessary to separately arrange a pump or a pipe for supplying the cooling medium, the sterilization effect can be efficiently obtained.

Note that when the end portion 52 of the supply flow path 5 connected to the processing chamber 20 is provided at a position apart from the end portion 61 of the downstream side flow path member 6, the fluid processing performance in the processing chamber 20 is improved. That is, in the supply flow path 5, the end portion 61 may be provided near one end (end face 202) of the processing chamber 20, and the end portion 52 may be provided near the other end (end face 201) of the processing chamber 20. However, the arrangement of the end portion 61 and the end portion 52 is not limited thereto. In the supply flow path 5, for example, the end portion 61 may be provided near the end face 201 of the processing chamber 20, and the end portion 52 may be provided near the end face 202 of the processing chamber 20.

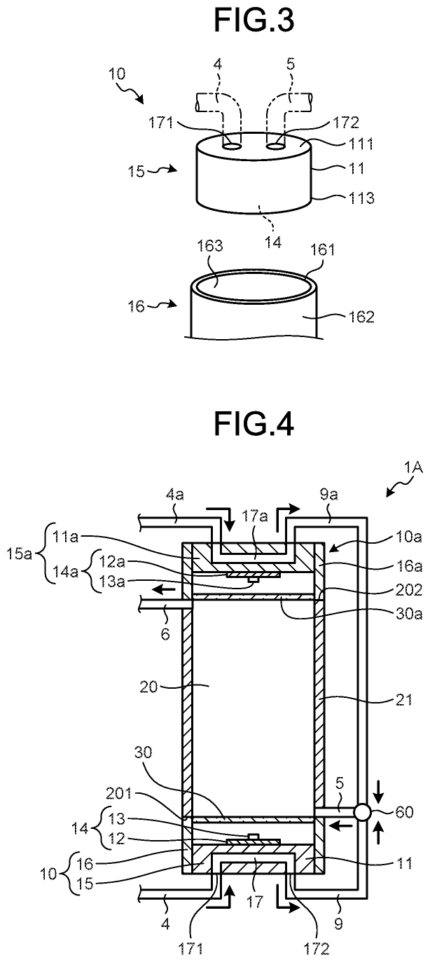

Here, attachment and detachment of the mounting portion 15 of the light source unit 10 will be described with reference to FIGS. 2 and 3. FIG. 3 is a schematic diagram illustrating the mounting portion according to the first embodiment.

The light source unit 10 includes the mounting portion 15 and a fixing portion 16. The mounting portion 15 includes the cooling block 11 having a substantially cylindrical shape and the light source 14. The fixing portion 16 has an inner surface 163 corresponding to a peripheral surface 113 of the cooling block 11. In the light source unit 10, by inserting the mounting portion 15 along the inner surface 163 of the fixing portion 16, the mounting portion 15 and the fixing portion 16 engage with each other, and the mounting portion 15 is detachably attached to the fixing portion 16. As described above, the light source unit 10 is configured such that the mounting portion 15 including the cooling block 11 having the medium flow path 17 is attachable and detachable at one end, thereby facilitating maintenance work including inspection and replacement of the light source unit 10.

Here, the back surface 111 of the cooling block 11 may be mounted so as to be flush with the end face 161 of the fixing portion 16, or may protrude from or be recessed from the end face 161. Further, the mounting portion 15 and the fixing portion 16 may be engaged by any method such as screwing or fitting. Further, the mounting portion 15 may be detachably mounted using a fastening member (not illustrated). Further, the light source unit 10 may be configured such that an outer surface 162 of the fixing portion 16 and the mounting portion 15 are engaged with each other. Further, the mounting portion 15 may be configured such that the light source unit 10 and the cover member 30 are integrally and detachably mounted on the end face 201 of the processing chamber 20.

### Second Embodiment

FIG. 4 is a schematic cross-sectional view illustrating a main part of a fluid sterilizer according to a second embodiment. A fluid sterilizer 1A illustrated in FIG. 4 is different from the fluid sterilizer 1 according to the first embodiment in that the fluid sterilizer 1A further includes a cover member 30a and a light source unit 10a facing the cover member 30 and the light source unit 10 with the processing chamber 20 interposed therebetween.

The light source unit 10a has the same configuration as that of the light source unit 10. That is, the light source unit 10a has a mounting portion 15a and the fixing portion 16a. The mounting portion 15a includes a light source 14a including a substrate 12a and a light-emitting element 13a, and a cooling block 11a having a medium flow path 17a. By disposing a plurality of light sources 14 and 14a having different irradiation directions in this way, the sterilization performance of the fluid sterilizer 1A is further enhanced. Note that each member included in the cover member 30a and the light source unit 10a can be the same as that of the cover member 30 and the light source unit 10. Therefore, detailed description of the cover member 30a and the light source unit 10a is omitted.

The upstream side flow path member 4 connected to the supply tank 2 and a connection flow path 9 connected to a connection portion 60 are connected to the medium flow path 17. In addition, an upstream side flow path member 4a connected to the supply tank 2 and a connection flow path 9a connected to the connection portion 60 are connected to the medium flow path 17a. That is, the medium flow paths 17 and 17a are connected in parallel via the connection flow paths 9 and 9a connected to the connection portion 60.

In addition, one end of the supply flow path 5 is connected to the connection portion 60 and the other end is connected to the processing chamber 20. The supply flow path 5 supplies the fluid flowing through the medium flow paths 17 and 17a to the processing chamber 20. By providing the supply flow path 5 and the connection flow paths 9 and 9a in this way, the fluid sterilizer 1A can use the fluid before processing in the processing chamber 20 as a cooling medium. Since a pump or a pipe for supplying a cooling medium may not be separately arranged in the fluid sterilizer 1A, the sterilization effect can be efficiently obtained. Note that the connection flow paths 9 and 9a may be individually connected to the processing chamber 20 without being joined at the connection portion 60.

In the present embodiment, the medium flow paths 17 and 17a are connected in parallel to the light source units 10 and 10a. By adopting such a configuration, the fluid sterilizer 1A is unlikely to have a difference in cooling ability between the light source units 10 and 10a. For this reason, in the fluid sterilizer 1A, a difference in the amount of ultraviolet light emitted from the light source units 10 and 10a toward the medium flow paths 17 and 17a hardly occurs, and as a result, the sterilization performance is enhanced. Further, since the medium flow paths 17 and 17a are connected in parallel to the light source units 10 and 10a, temperatures of the cooling media reaching the light source units 10 and 10a become substantially equal. For this reason, a difference in deterioration between the light sources 14 and 14a due to heat emitted from the light source units 10 and 10a hardly occurs. When there is no difference in deterioration between the light sources 14 and 14a, the light sources 14 and 14a can be replaced, that is, the light source units 10 and 10a can be replaced at the same time. As a result, it is possible to reduce the maintenance frequency of the fluid sterilizer 1A.

### Third Embodiment

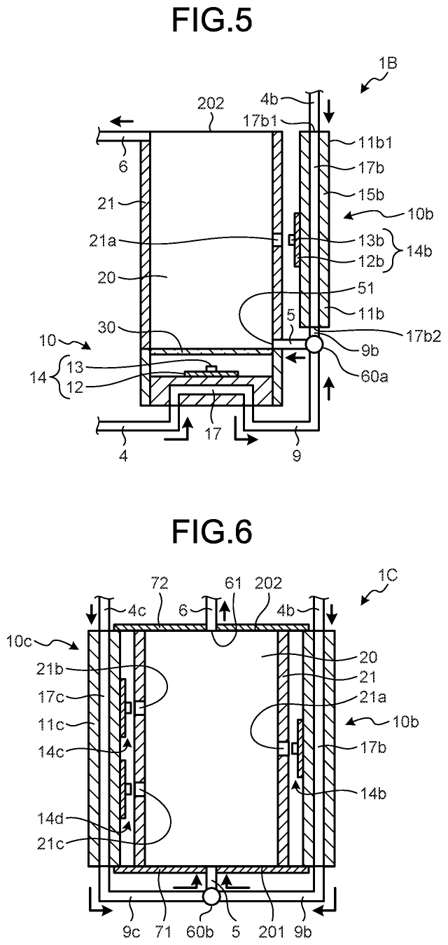

FIG. 5 is a schematic cross-sectional view illustrating a main part of a fluid sterilizer according to a third embodiment. A fluid sterilizer 1B illustrated in FIG. 5 is different from the fluid sterilizer 1 according to the first embodiment in that the fluid sterilizer 1B further includes a light source unit 10b facing a side surface of the processing chamber 20.

The light source unit 10b includes a light source 14b including a substrate 12b and a light-emitting element 13b, and a cooling block 11b having a medium flow path 17b. Further, the reflection plate 21 facing the light source 14b has an opening 21a for irradiating the processing chamber 20 with ultraviolet rays from the light source 14b. As described above, in the fluid sterilizer 1B, the sterilization performance is further enhanced by disposing a plurality of light sources 14 and 14b having different irradiation directions. Note that each member included in the light source unit 10b can be the same as that of the light source unit 10. For this reason, detailed description of the light source unit 10b is omitted.

The upstream side flow path member 4 connected to the supply tank 2 and the connection flow path 9 connected to the connection portion 60a are connected to the medium flow path 17. Further, the upstream side flow path member 4b connected to the supply tank 2 and the connection flow path 9b connected to the connection portion 60a are connected to the medium flow path 17b. That is, the medium flow paths 17 and 17b are connected in parallel via the connection flow paths 9 and 9b connected to the connection portion 60a.

Note that even though the medium flow path 17b is illustrated as having openings 17b1 and 17b2 formed on a side surface of the cooling block 11b, the medium flow path 17b is not limited thereto and may have the openings 17b1 and 17b2 formed on a back surface 11b1 of the cooling block 11b. Further, the light source unit 10b may be configured as a mounting portion 15b that is attachable to and detachable from the fluid sterilizer 1B.

Further, one end of the supply flow path 5 is connected to the connection portion 60a, and the other end is connected to the processing chamber 20. The supply flow path 5 supplies the fluid flowing through the medium flow paths 17 and 17b to the processing chamber 20. As described above, by providing the supply flow path 5 and the connection flow paths 9 and 9b, the fluid sterilizer 1B can use the fluid before processing in the processing chamber 20 as a cooling medium. Since a pump or a pipe for supplying a cooling medium may not be separately arranged in the fluid sterilizer 1B, the sterilization effect can be efficiently obtained. Note that the connection flow paths 9 and 9b may be individually connected to the processing chamber 20 without being joined at the connection portion 60a.

Further, by connecting the medium flow paths 17 and 17b in series to the light source units 10 and 10b, a flow path configuration can be simplified and the fluid sterilizer 1B can be easily assembled. Further, by connecting the medium flow paths 17 and 17b in series to the light source units 10 and 10b, it is possible to easily adjust the flow rate of the fluid flowing into the medium flow paths 17 and 17b, that is, the fluid sterilizer 1B.

### Fourth Embodiment

FIG. 6 is a schematic cross-sectional view illustrating a main part of a fluid sterilizer according to a fourth embodiment. A fluid sterilizer 1C illustrated in FIG. 6 is different from the fluid sterilizer 1B according to the third embodiment in that the fluid sterilizer 1C further includes a light source unit 10c that faces the light source unit 10b with the processing chamber 20 interposed therebetween instead of the light source unit 10 and the cover member 30.

The light source unit 10c includes a light source 14c including a substrate 12c and a light-emitting element 13c, a light source 14d including a substrate 12d and a light-emitting element 13d, and a cooling block 11c having a medium flow path 17c. Further, the reflection plate 21 facing the light sources 14c and 14d has openings 21b and 21c for irradiating the processing chamber 20 with ultraviolet rays from the light sources 14c and 14d. As described above, the fluid sterilizer 1C can improve the sterilization performance by disposing a plurality of light sources 14b to 14d having different irradiation directions. Furthermore, in the fluid sterilizer 1C, when reflection plates 71 and 72 are provided on end faces 201 and 202 of the processing chamber 20, the sterilization performance is further enhanced. Note that each member included in the light sources 14c and 14d may be the same as that of the light source 14. For this reason, detailed description of the light sources 14c and 14d is omitted.

The cooling block 11c supports the light sources 14c and 14d by fixing the substrates on which the light-emitting elements are mounted at predetermined positions. The upstream side flow path member 4b connected to the supply tank 2 and the connection flow path 9b connected to a connection portion 60b are connected to the medium flow path 17b. Further, the upstream side flow path member 4c connected to the supply tank 2 and a connection flow path 9c connected to the connection portion 60b are connected to the medium flow path 17c. That is, the medium flow paths 17b and 17c are connected in parallel via the connection flow paths 9b and 9c connected to the connection portion 60b.

Note that even though the cooling block 11c is illustrated as supporting the two light sources 14c and 14d, the cooling block 11c is not limited thereto and may support one or three or more light sources. Further, even though the light sources 14c and 14d are illustrated to face the light source unit 10b, that is, a difference in irradiation direction is 180°, the light sources 14c and 14d are not limited thereto. For example, the difference in irradiation direction may be about 30° to 120°. Further, the light source unit 10c may be configured to be attachable to and detachable from the fluid sterilizer 1C.

In addition, one end of the supply flow path 5 is connected to the connection portion 60b and the other end is connected to the processing chamber 20. The supply flow path 5 supplies the fluid flowing through the medium flow paths 17b and 17c to the processing chamber 20. As described above, by providing the supply flow path 5 and the connection flow paths 9b and 9c, the fluid sterilizer 1C can use the fluid before processing in the processing chamber 20 as a cooling medium. Since a pump or a pipe for supplying a cooling medium may not be separately arranged in the fluid sterilizer 1C, the sterilization effect can be efficiently obtained. Note that the connection flow paths 9b and 9c may be individually connected to the processing chamber 20 without being joined at the connection portion 60b.

### Fifth Embodiment

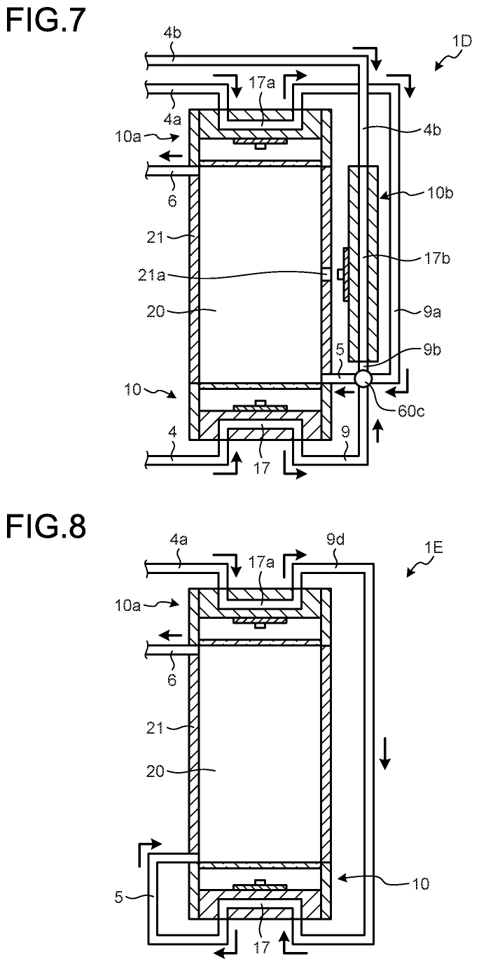

FIG. 7 is a schematic cross-sectional view illustrating a main part of a fluid sterilizer according to a fifth embodiment. A fluid sterilizer 1D illustrated in FIG. 7 is different from the fluid sterilizer 1A according to the second embodiment in that the fluid sterilizer 1D further includes a light source unit 10b that faces a side surface of the processing chamber 20. As described above, in the fluid sterilizer 1D, the sterilization performance can be enhanced by disposing the light source units 10, 10a, and 10b including a plurality of light sources having different irradiation directions.

The medium flow path 17 is connected to the upstream side flow path member 4 connected to the supply tank 2 and the connection flow path 9 connected to a connection portion 60c. In addition, the medium flow path 17a is connected to the upstream side flow path member 4a connected to the supply tank 2 and the connection flow path 9a connected to the connection portion 60c. Further, the medium flow path 17b is connected to the upstream side flow path member 4b connected to the supply tank 2 and the connection flow path 9b connected to the connection portion 60c. That is, the medium flow paths 17, 17a, and 17b are connected in parallel via the connection flow paths 9, 9a, and 9b connected to the connection portion 60c.

In addition, one end of the supply flow path 5 is connected to the connection portion 60c and the other end is connected to the processing chamber 20. The supply flow path 5 supplies the fluid flowing through the medium flow paths 17, 17a, and 17b to the processing chamber 20. By providing the supply flow path 5 and the connection flow paths 9, 9a, and 9b in this way, the fluid sterilizer 1D can use the fluid before processing in the processing chamber 20 as a cooling medium. Since a pump or a pipe for supplying a cooling medium may not be separately arranged in the fluid sterilizer 1D, the sterilization effect can be efficiently obtained. Note that the connection flow paths 9, 9a, and 9b may be individually connected to the processing chamber 20 without being joined at the connection portion 60c.

### Sixth Embodiment

FIG. 8 is a schematic cross-sectional view illustrating a main part of a fluid sterilizer according to a sixth embodiment. A fluid sterilizer 1E illustrated in FIG. 8 has the same configuration as that of the fluid sterilizer 1A according to the second embodiment except that configurations of flow paths connected to the medium flow paths 17 and 17a are different.

The upstream side flow path member 4a connected to the supply tank 2 and a connection flow path 9d are connected to the medium flow path 17a. In addition, the connection flow path 9d and the supply flow path 5 are connected to the medium flow path 17. That is, the medium flow paths 17 and 17a are connected in series via the connection flow path 9d.

In addition, one end of the supply flow path 5 is connected to the medium flow path 17 and the other end is connected to the processing chamber 20. The supply flow path 5 supplies the fluid flowing through the medium flow paths 17a and 17 to the processing chamber 20. By providing the supply flow path 5 and the connection flow path 9d in this way, the fluid sterilizer 1E can use the fluid before processing in the processing chamber 20 as a cooling medium. Since a pump or a pipe for supplying a cooling medium may not be separately arranged in the fluid sterilizer 1E, the sterilization effect can be efficiently obtained.

### Seventh Embodiment

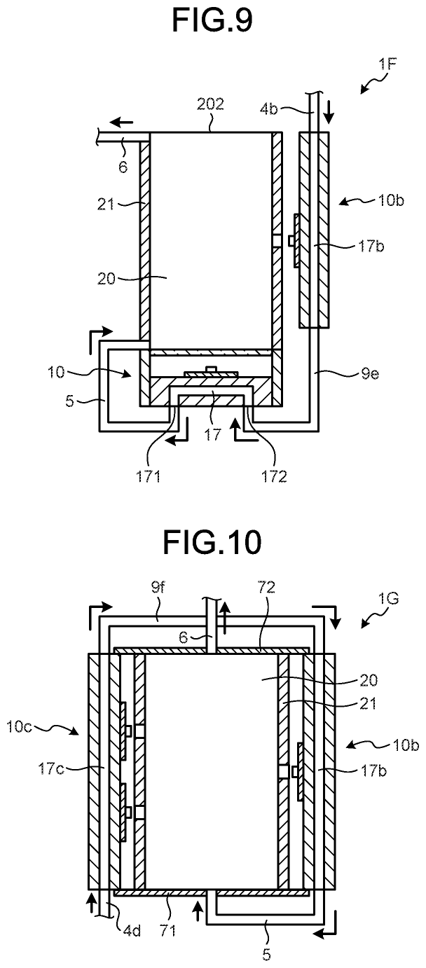

FIG. 9 is a schematic cross-sectional view illustrating a main part of a fluid sterilizer according to a seventh embodiment. A fluid sterilizer 1F illustrated in FIG. 9 has the same configuration as that of the fluid sterilizer 1B according to the third embodiment except that configurations of flow paths connected to the medium flow paths 17 and 17b are different.

The upstream side flow path member 4b connected to the supply tank 2 and a connection flow path 9e are connected to the medium flow path 17b. In addition, the medium flow path 17 is connected to the connection flow path 9e and the supply flow path 5. That is, the medium flow paths 17b and 17 are connected in series via the connection flow path 9e.

In addition, one end of the supply flow path 5 is connected to the medium flow path 17 and the other end is connected to the processing chamber 20. The supply flow path 5 supplies the fluid flowing through the medium flow paths 17b and 17 to the processing chamber 20. By providing the supply flow path 5 and the connection flow path 9e in this way, the fluid sterilizer 1F can use the fluid before processing in the processing chamber 20 as a cooling medium. Since a pump or a pipe for supplying a cooling medium may not be separately arranged in the fluid sterilizer 1F, the sterilization effect can be efficiently obtained.

### Eighth Embodiment

FIG. 10 is a schematic cross-sectional view illustrating a main part of a fluid sterilizer according to an eighth embodiment. A fluid sterilizer 1G illustrated in FIG. 10 has the same configuration as that of the fluid sterilizer 1C according to the fourth embodiment except that configurations of flow paths connected to the medium flow paths 17b and 17c are different.

The medium flow path 17c is connected to an upstream side flow path member 4d connected to the supply tank 2 and a connection flow path 9f. In addition, the medium flow path 17b is connected to the connection flow path 9f and the supply flow path 5. That is, the medium flow paths 17c and 17b are connected in series via the connection flow path 9f.

In addition, one end of the supply flow path 5 is connected to the medium flow path 17b and the other end is connected to the processing chamber 20. The supply flow path 5 supplies the fluid flowing through the medium flow paths 17c and 17b to the processing chamber 20. By providing the supply flow path 5 and the connection flow path 9f in this way, the fluid sterilizer 1G can use the fluid before processing in the processing chamber 20 as a cooling medium. Since a pump or a pipe for supplying a cooling medium may not be separately arranged in the fluid sterilizer 1G, the sterilization effect can be efficiently obtained.

### Ninth Embodiment

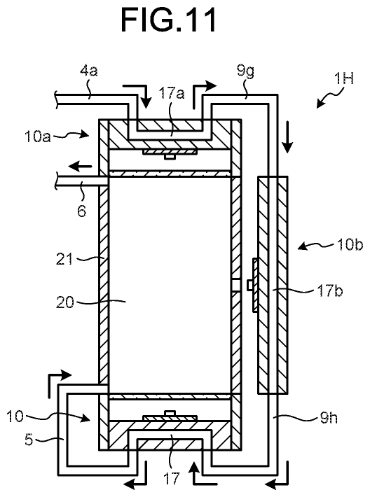

FIG. 11 is a schematic cross-sectional view illustrating a main part of a fluid sterilizer according to a ninth embodiment. A fluid sterilizer 1H illustrated in FIG. 11 has the same configuration as that of the fluid sterilizer 1D according to the fifth embodiment except that configurations of flow paths connected to the medium flow paths 17, 17a, and 17b are different.

The medium flow path 17a is connected to the upstream side flow path member 4a connected to the supply tank 2 and a connection flow path 9g. In addition, the medium flow path 17b is connected to the connection flow path 9g and a connection flow path 9h. Further, the medium flow path 17 is connected to the connection flow path 9h and the supply flow path 5. That is, the medium flow paths 17a, 17b, and 17 are connected in series via the connection flow paths 9g and 9h.

In addition, one end of the supply flow path 5 is connected to the medium flow path 17 and the other end is connected to the processing chamber 20. The supply flow path 5 supplies the fluid flowing through the medium flow paths 17a, 17b, and 17 to the processing chamber 20. By providing the supply flow path 5 and the connection flow paths 9g and 9h in this way, the fluid sterilizer 1H can use the fluid before processing in the processing chamber 20 as a cooling medium. Since a pump or a pipe for supplying a cooling medium may not be separately arranged in the fluid sterilizer 1H, the sterilization effect can be efficiently obtained.

As described above, the fluid sterilizer 1 according to the embodiment includes the processing chamber 20, the light source units 10, 10a to 10c, and the supply flow path 5. The processing chamber 20 processes the fluid. The light source units 10, 10a to 10c has the light source 14, the cooling block 11, and the medium flow path 17. The light source 14 emits ultraviolet rays toward the processing chamber 20. The cooling block 11 cools the light source 14. The medium flow path 17 is provided inside the cooling block 11, and a cooling medium flows therein. The supply flow path 5 connects the medium flow path 17 and the processing chamber 20 to each other, and supplies the cooling medium flowing through the medium flow path 17 to the processing chamber 20 as the fluid. For this reason, it is possible to efficiently obtain the sterilization effect. In addition, the fluid sterilizer 1 uses the fluid supplied to the processing chamber 20 as a cooling medium of the light source unit 10. In this case, that is, when the fluid sterilizer 1 uses the fluid after an ultraviolet ray treatment as the cooling medium of the light source unit 10, the fluid irradiated with the ultraviolet rays generates heat by the ultraviolet ray irradiation and the temperature of the fluid rises. For this reason, it is difficult to control the temperature of the fluid. When the temperature control of the fluid is difficult, the light source unit 10 is insufficiently cooled when the temperature of the fluid rises, and the sterilization effect may not be efficiently obtained. In particular, under the condition that the fluid processed by the fluid sterilizer 1 exceeds 10 L per minute, the temperature control is more difficult. On the other hand, in the fluid sterilizer 1 according to the embodiment, since the cooling medium for the light source unit 10 is supplied to the processing chamber, the light source unit 10 can be cooled without increasing the temperature of the fluid. That is, in the fluid sterilizer 1 according to the present embodiment, the temperature control of the fluid becomes easier when compared to a case where the fluid supplied to the processing chamber 20 is used as the cooling medium of the light source unit 10. Therefore, the fluid sterilizer 1 can efficiently irradiate the fluid with the ultraviolet rays emitted from the light source unit 10, and thus can efficiently obtain the sterilization effect.

In addition, the light source units 10, 10a to 10c according to the embodiments include a plurality of light sources 14 having different irradiation directions. Therefore, the sterilization effect is further enhanced.

In addition, the light source units 10b and 10c according to the embodiment have the light source 14b facing the side surface 203 of the processing chamber 20. Therefore, the sterilization effect is further enhanced.

In addition, the light source units 10, 10a to 10c according to the embodiments have the plurality of cooling blocks 11, 11a to 11c in which the medium flow paths 17, 17a to 17c are connected in parallel via the connection flow paths 9, 9a to 9c. Therefore, the sterilization effect is further enhanced.

In addition, the light source units 10, 10a to 10c according to the embodiments have the plurality of cooling blocks 11, 11a to 11c in which the medium flow paths 17, 17a to 17c are connected in parallel via the connection flow paths 9d to 9f. Therefore, the sterilization effect is further enhanced.

Further, in the fluid sterilizer 1 according to the embodiment, at least a part of the light source units 10, 10a to 10c including the medium flow paths 17, 17a to 17c is detachably mounted. Therefore, the light source units 10, 10a to 10c can be easily replaced.

Note that the configuration of the fluid sterilizer according to each embodiment is not limited to the illustrated one. For example, it is possible to have both a configuration in which the plurality of cooling blocks is connected in parallel via the connection flow paths and a configuration in which the plurality of cooling blocks is connected in series. In this way, a degree of freedom in flow path design increases.

Moreover, the fluid sterilizer according to each embodiment may be used in any orientation. For example, the fluid sterilizer may be used with the end face 202 of the processing chamber 20 facing upward and the end face 201 facing downward, or with the end face 201 facing upward and the end face 202 facing downward. Furthermore, in the fluid sterilizer, the side surface 203 of the processing chamber 20 may horizontally arranged, or tilted and used.

Even though some embodiments have been described, these embodiments are presented as examples and are not intended to limit the scope of the invention. These embodiments can be implemented in various other forms, and various omissions, replacements, and changes can be made without departing from the spirit of the invention. These embodiments and modifications thereof are included in the invention described in the claims and the equivalents thereof as well as included in the scope and the spirit of the invention.

What is claimed is:

1. A fluid sterilizer comprising:
a processing chamber for processing a fluid;
a light source unit having a light source for irradiating the processing chamber with ultraviolet rays, a cooling block for cooling the light source, and a medium flow path provided inside the cooling block, a cooling medium flowing through the medium flow path; and
a supply flow path for connecting the medium flow path and the processing chamber to each other and supplying the cooling medium flowing through the medium flow path to the processing chamber as the fluid.

2. The sterilizer according to claim 1, wherein the light source unit has a plurality of light sources having different irradiation directions.

3. The sterilizer according to claim 1, wherein the light source unit has the light source facing a side surface of the processing chamber.

4. The sterilizer according to claim 2, wherein the light source unit has the light source facing a side surface of the processing chamber.

5. The sterilizer according to claim 1, wherein the light source unit has a plurality of cooling blocks in which medium flow paths are connected in parallel via connection flow paths.

6. The sterilizer according to claim 2, wherein the light source unit has a plurality of cooling blocks in which medium flow paths are connected in parallel via connection flow paths.

7. The sterilizer according to claim 3, wherein the light source unit has a plurality of cooling blocks in which medium flow paths are connected in parallel via connection flow paths.

8. The sterilizer according to claim 4, wherein the light source unit has a plurality of cooling blocks in which medium flow paths are connected in parallel via connection flow paths.

9. The sterilizer according to claim 1, wherein the light source unit has a plurality of cooling blocks in which medium flow paths are connected in series via a connection flow path.

10. The sterilizer according to claim 2, wherein the light source unit has a plurality of cooling blocks in which medium flow paths are connected in series via a connection flow path.

11. The sterilizer according to claim 3, wherein the light source unit has a plurality of cooling blocks in which medium flow paths are connected in series via a connection flow path.

12. The sterilizer according to claim 4, wherein the light source unit has a plurality of cooling blocks in which medium flow paths are connected in series via a connection flow path.

13. The sterilizer according to claim 1, wherein at least a part of the light source unit including the medium flow path is detachably mounted.

14. The sterilizer according to claim 2, wherein at least a part of the light source unit including the medium flow path is detachably mounted.

15. The sterilizer according to claim 3, wherein at least a part of the light source unit including the medium flow path is detachably mounted.

16. The sterilizer according to claim 4, wherein at least a part of the light source unit including the medium flow path is detachably mounted.

17. The sterilizer according to claim 5, wherein at least a part of the light source unit including the medium flow path is detachably mounted.

18. The sterilizer according to claim 6, wherein at least a part of the light source unit including the medium flow path is detachably mounted.

19. The sterilizer according to claim 9, wherein at least a part of the light source unit including the medium flow path is detachably mounted.

20. The sterilizer according to claim 10, wherein at least a part of the light source unit including the medium flow path is detachably mounted.
